(19) United States
(12) Patent Application Publication
(10) Pub. No.: US 2026/0370172 A1
(43) Pub. Date: Nov. 19, 2026

(54) ASYMMETRICAL DUAL INVERTER-BASED HIGH SPEED PERMANENT MAGNET SYNCHRONOUS MOTOR (PMSM) MOTOR DRIVE AND CONTROL METHOD

(71) Applicant: The Florida State University Research Foundation, Inc., Tallahassee, FL (US)

(72) Inventors: Hui Li, Tallahassee, FL (US); Oscar Lopez, Tallahassee, FL (US)

(21) Appl. No.: 19/355,597

(22) Filed: Oct. 10, 2025

Related U.S. Application Data
(60) Provisional application No. 63/705,683, filed on Oct. 10, 2024.

(51) Int. Cl. H02P 27/06; H02P 21/14; H02P 25/022; H03K 17/042

(52) U.S. Cl. CPC H02P 27/06; H02P 21/14; H02P 25/022; H03K 17/04206; H02P 2205/07; H02P 2209/05; H02P 2209/11

(57) ABSTRACT

Systems, devices, and methods of an asymmetrical dual inverter motor drive are described herein.

### CROSS REFERENCE TO RELATED APPLICATION

This application claims priority to and benefit of U.S. provisional patent application Ser. No. 63/705,683 filed Oct. 10, 2024, which is fully incorporated by reference.

### GOVERNMENT SUPPORT

This invention was made with government support under Grant no. DE-AR0001359 awarded by the Department of Energy. The government has certain rights in the invention.

### BACKGROUND

Current motor drives for high speed motors usually require the use of a multilevel topology to guarantee low current harmonics in the machine terminals, which comes at the cost of a large reduction in power density. For example, while the application of SiC MOSFETs in the field transportation has brought many benefits, replacing silicon insulated-gate bipolar transistor devices (Si-IGBTs) with SiC MOSFETs introduces several new technical challenges, such as stronger electromagnetic interference (EMI), reliability issues, potential electric machine insulation failure due to high transient voltages, and cooling difficulties. Compared to mature Si-based semiconductor technologies, these challenges have so far hindered the widespread adoption of SiC MOSFETs in some applications such as electric aircraft (EA) and/or electric vehicle (EV) applications. To fully exploit the advantages of SiC MOSFETs in transportation applications it is necessary to first have a good understanding of the challenges in using this technology faces.

Challenges caused by the higher switching speed (higher dv/dt) of SiC devices may include high motor terminal overvoltage. For example, more severe reflective waves occur if the cable between the motor and inverter is long with respect to the switching speed. With full reflection occurring at the motor terminal if the propagation time of the cable is greater than ⅓ the rise time.

Additional challenges may include higher insulation stress and partial discharge risk. Partial discharge (PD) is a localized dielectric breakdown of a small portion of a solid or fluid electrical insulation (EI) system under high voltage (HV) stress. As expected, the higher voltages of SiC devices will significantly increase the required weight and size of insulation layers. Additionally, it has been shown that the voltage slew rate dominates over other factors that influence PD inception and magnitude. Furthermore, the chance of partial discharge is also affected by air pressure, increasing significantly at low pressures, making it especially crucial to consider for (EA) applications. Another challenge that may be faced includes increased EMI Generation. SiC devices can generate more conducted EMI than Si devices because of their ability to operate at higher frequencies and switch faster. This EMI can cause problems in motor drive inverter applications, such as ground leakage current, motor bearing failures, and audio susceptibility issues. These problems can become more serious when SiC devices are used to build motor drive inverters that operate at higher switching frequencies. Additionally, the thermal challenges arising from the SiC devices physical characteristics should be considered. The increased power draw capabilities combined with lower chip size leads to greater loss density and higher heat flux for SiC switches, even when taking into account their higher efficiency. Furthermore, their lower mass, while useful for high power density designs, reduce the temperature rise time constant. The short circuit capabilities of SiC MOSFET devices is mainly restricted by a high short circuit current density. The increased ratio of heat generation to heat conduction leads to fast junction temperature rise during short circuit scenarios, reducing the overall reliability of the SiC inverter systems, if not taken into account.

Therefore, systems, methods and devices are desired that overcome challenges in the art, some of which are described above.

### SUMMARY

Systems, devices, and methods are described herein that overcome the above-described disadvantages. In order to achieve the high power density necessary in EV applications (which includes EVs and EA), while maintaining low harmonics for the high-speed low inductance machines used, an asymmetrical dual inverter motor drive topology is disclosed. In this topology each inverter module's DC link is isolated and has an independent voltage, which allows the drive to output a multilevel voltage at the machine terminals while only using conventional two-level inverter modules. Additionally, this topology also provides an additional control vector through the voltage ratio between both inverter's DC. Adjusting the ratio between them changes the number of levels and maximum voltage achievable at the output.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 illustrates topology of an exemplary asymmetrical dual inverter motor drive for a 3-phase machine.

FIG. 2 illustrates topology of an exemplary asymmetrical dual inverter motor drive for a 6-phase machine.

FIG. 3A illustrates a vector space diagram for a 1:2 voltage ratio and FIG. 3B illustrates a vector space diagram for a 1:1 voltage ratio.

FIG. 4 illustrates an exemplary control schematic for controlling a three-phase asymmetrical dual inverter motor drive using model predictive control (MPC).

FIG. 5 illustrates an exemplary compact gate charge pump (GCP) gate driver (GD) for testing aspects described herein.

FIG. 6 illustrates exemplary turn-on waveform comparison of conventional and the disclosed gate driver where FIG. 6A illustrates a conventional GD, measured Eₒₙ=8.4 mJ @ iₛₘₐₓ=195 A; and FIG. 6B illustrates the disclosed GCP GD, measured Eₒₙ=5.1 mJ @ iₛₘₐₓ=195 A.

FIG. 7 is a graph that compares Eₒₙ curves of 2-L and GCP driving modes at Vcc/Vee=+20 V/−5 V.

FIG. 8 is an illustration of an exemplary pump-back test circuit schematic.

FIG. 9 is an image of an exemplary fabricated inductive load bank for testing aspects described herein.

FIG. 10 is a table illustrating an arrangement of 15 units of single inductors for different phase A/B/C for the load bank shown in FIG. 9.

FIG. 11 illustrates exemplary motor parameters according to some aspects disclosed herein.

FIG. 12 illustrates a comparison of performance results for various motor drive topologies, including embodiments described herein.

FIG. 13 illustrates voltage and current waveforms comparison among the various topologies referenced in FIG. 12.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising”, and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. As used herein, “exemplary” means an example of and is not intended to denote a preference or a preferred embodiment. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

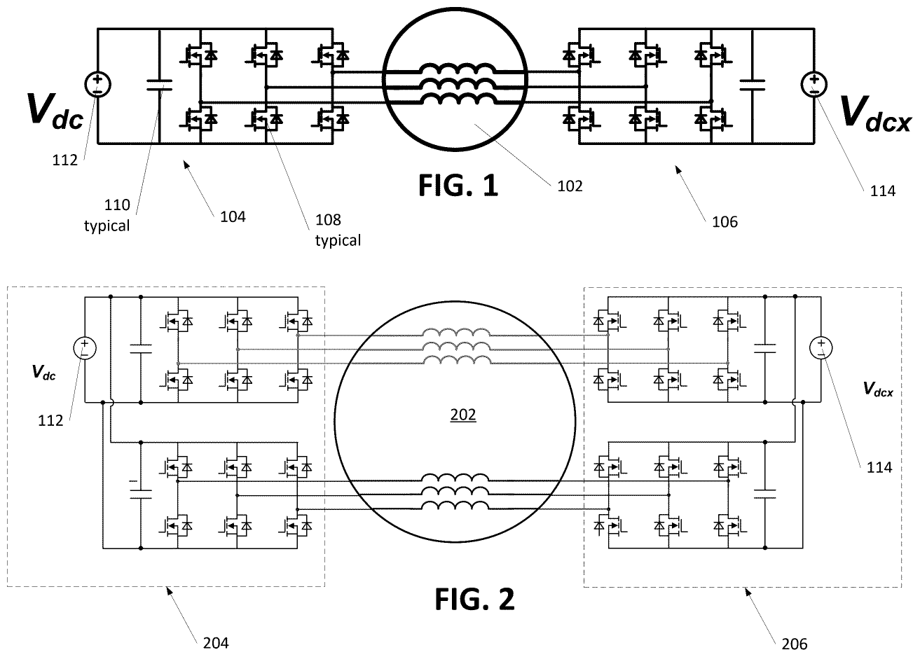

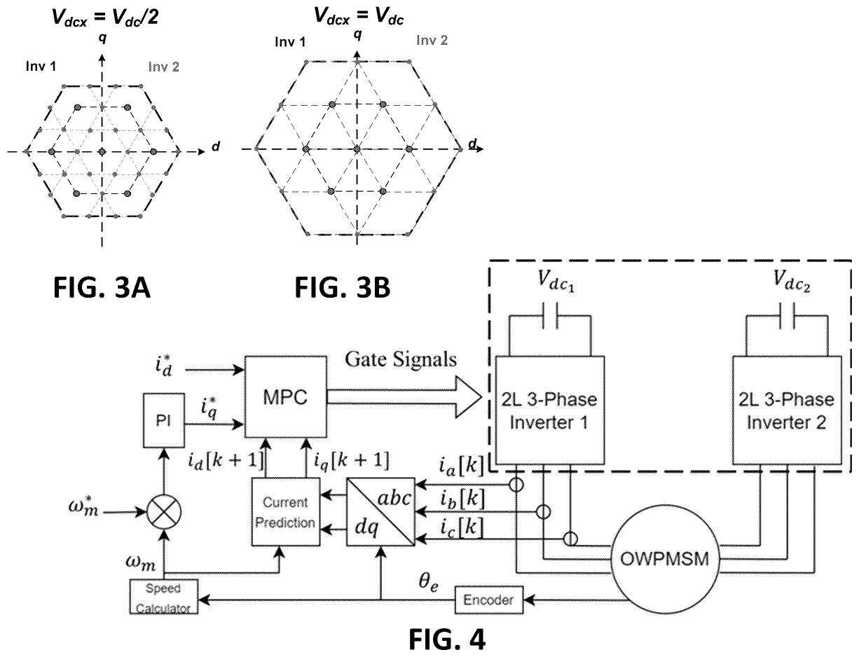

FIG. 1 illustrates topology of an exemplary asymmetrical dual inverter motor drive for a 3-phase machine. Similarly, the topology of an asymmetrical dual inverter motor drive for 6-phase open-winding machines is illustrated in FIG. 2. In each instance, each inverter module's DC link is isolated and has an independent voltage. Using the disclosed topology, the drive can achieve a multilevel voltage output at the machine terminals by using only two-level inverters, which is ideal for high-speed low inertia machine applications that require high efficiency and power density. Adjusting the ratio between both inverter's DC voltages allows changing the number of output voltage levels and maximum voltage achievable at the output, as shown in the maximum distention space vector diagrams of FIGS. 3A and 3B, where FIG. 3A illustrates a vector space diagram for a 1:2 voltage ratio and FIG. 3B illustrates a vector space diagram for a 1:1 voltage ratio. This adjustable characteristic increases the available design space of the topologies.

FIG. 4 is a control schematic for controlling a three-phase asymmetrical dual inverter motor drive. A similar control system can be utilized for a six-phase embodiment of the motor drive. By using a selective model predictive control (MPC) algorithm that limits the vector search space, a fast dynamic response can be achieved while maintaining clean output currents.

FIG. 1 illustrates a three-phase open-winding permanent magnet synchronous motor (OWPMSM) 102 connect to a first inverter 104 and a second inverter 106. Each inverter is comprised of a plurality of solid-state switching devices 108, such as SiC switching devices. Generally, there will be two switching devices 108 for each phase, with a parallel capacitor 110 to help control voltage ripple and transients. In some instances, the switching devices 108 comprise SiC switching devices. In some instances, the SiC switching devices comprise SiC MOSFETs. Each inverter 104, 106 is connected to a DC voltage source 112, 114. A control system, such as the control system shown in FIG. 4 and described herein, sends gate signals to each SiC device 108 to turn them on (conducting) or off (non-conducting). In this way, each inverter 104, 106 provides three-phase AC power to the windings of motor 102. By adjusting the ratio between both inverter's DC voltage 112, 114, allows changing the number of output voltage levels and maximum voltage achievable at the output of each inverter 104, 106. Similarly, FIG. 2 illustrates a six-phase embodiment comprising additional switching devices 108 connected to the same voltage sources 112, 114 as the inverters 104, 106 of FIG. 1. In this way, each inverter 204, 206 provides six-phase AC power to six-phase motor 202.

As noted herein, FIG. 4 illustrates an exemplary control system using MPC to send gate signals to the switching devices 108 of the inverters. By adjusting the firing of the different gates of the switching devices, angles between the various phases can be achieved, as desired.

The Model Predictive Control (MPC) structure provides a fast dynamic response, intuitive control design and tuning, and can reduce the overall switching frequency by penalizing unnecessary switching transitions through its cost function. One of the main advantages of this topology is that it allows for a multi-level output voltage generation

### EXAMPLES

Below are provided non-limiting examples of experimental testing of embodiments of the disclosed invention.

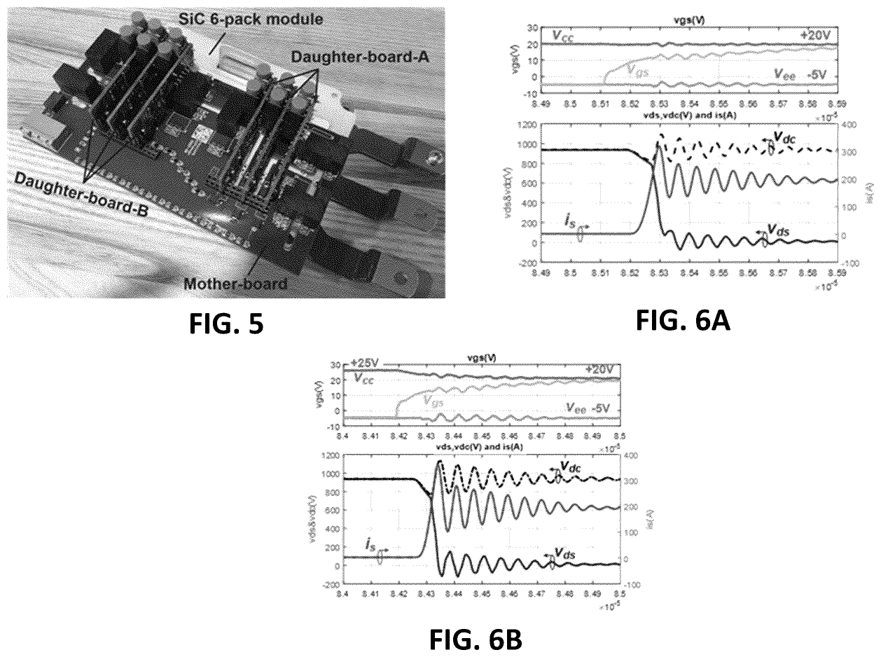

A compact gate charge pump (GCP) gate driver (GD) is proposed and built, as shown in FIG. 5. Double-pulse test (DPT) experiments using the proposed GCP were conducted to evaluate the switching loss improvement by the disclosed solution. Compared to conventional 2-L GDs, the proposed GCP outputs a higher driving voltage during switching transients to increase the switching speed, but maintains the same steady-state driving voltage to avoid extra voltage stress on the gate terminal. FIG. 6A shows the turn-on waveform with proposed GCP driving mode at Vcc/Vee=+20 V/−5 V (i.e., recommended steady-state driving voltage), Ron=Roff=2.5Ω, and ismax=195 A. As shown in FIG. 6A, Vcc is charged to +25 V before the turn-on transient, then decreases during the turn-on transient, and finally recovers to +20 V after the turn-on transient. Note that the actual gate-source voltage (vgs) always remains within (−5V, +20V), which means that proposed GCP driving mode will not induce extra voltage stress on the gate terminal. FIG. 6B illustrates GCP GD, measured Eₒₙ=5.1 mJ @ iₛₘₐₓ=195 A.

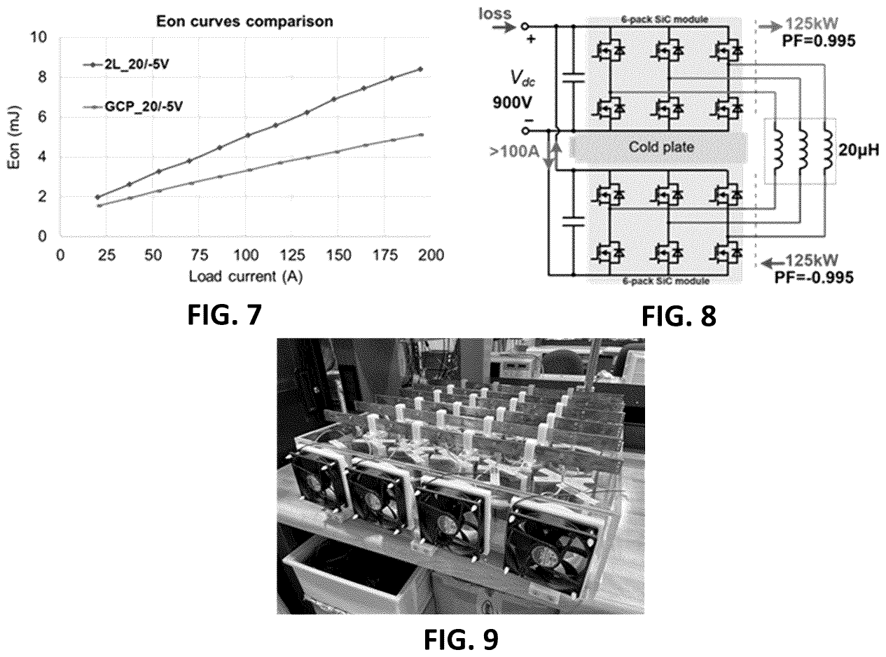

Compared with 2-L driving mode waveform shown in FIG. 6B, both the dv/dt of vds and di/dt of iₛ are higher by the proposed GCP driving mode, Eₒₙ is therefore reduced from 8.4 mJ to 5.1 mJ. FIG. 7 compares Eₒₙ curves of 2-L and GCP driving modes at Vcc/Vee=+20 V/−5 V. It is concluded that proposed GCP driving mode enables a much lower Eₒₙ within the whole load range. Additionally, note that the proposed design remains a light weight of 126 g to achieve the high power density of motor drive. Furthermore, the proposed GD hardware has been validated in a preliminary 3-phase inverter test with a robust noise immunity to the high dv/dt environment.

To test the inverter's drive operation before using the motor, the pump-back test configuration in which the power is circulated between two inverters, as shown in FIG. 8, and which operates similarly to the open winding configuration was chosen. These two inverters operate at the same modulation index of 0.9, but with a specific phase shift angle, which is determined based on the expected pump-back circulating power.

In order to perform these tests, an inductive load bank with an inductance less than 22 μH per phase, closely matching the machine inductance parameter, was designed and assembled. FIG. 9 shows the picture of this fabricated inductive load bank hardware.

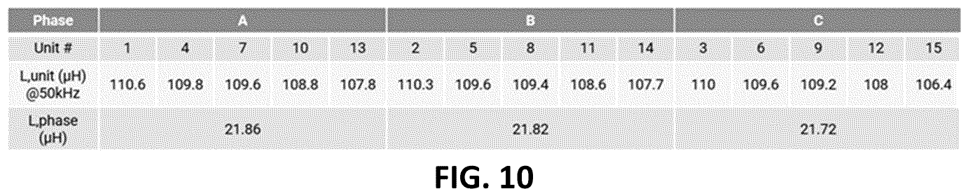

The new design maintains the same magnetic core, air gap and litz wires but features a reduced winding turn count of 19.5 turns, resulting in a higher saturation current up to 475 A. In FIG. 10, the arrangement of 15 units of single inductors for different phase A/B/C is presented, leading to equivalent inductances of 21.86 μH, 21.82 μH and 21.72 μH, respectively. Notably, the maximum inductance variation among phase A/B/C is less than 0.63%.

Though not described herein, additionally, necessary steps were taken to design and assemble the cooling loop needed to accommodate both inverter modules and their respective cold-plates. This loop was necessary to properly dissipate the heat generated by two power modules during the pump-back tests. The existing chiller and flowmeter piping remained unchanged from the previous design. Only the fittings and sensors for the second cold-plate and the interfacing hose need to be added to the existing cooling system. The second cold-plate and necessary components have been procured, and the assembly process for the cooling loop's expansion is currently in process.

### Results

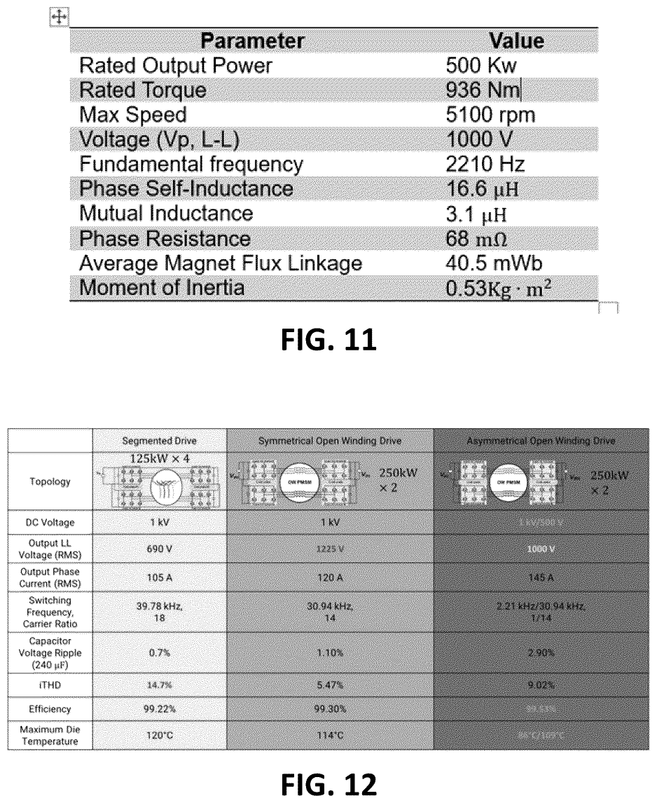

Using the high-speed motor parameters of FIG. 11, the disclosed drive topology is then compared to more conventional segmented and symmetrical open winding approaches through the use of steady state simulations using an RL-load approximation for the motor. The results shown in FIG. 12 clearly demonstrate the various advantages of the proposed topology, as it achieves the highest efficiency while still maintaining an acceptably low level of harmonic distortion in the currents.

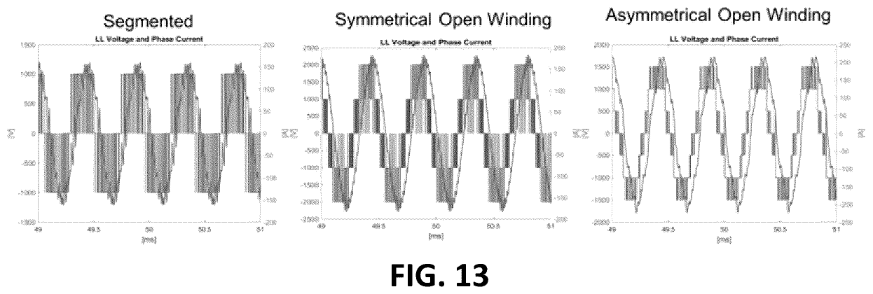

This is further showcased by the waveform comparisons of FIG. 13, in which the output currents that result from the higher number of voltage levels can be observed. Furthermore, its asymmetrical DC voltage nature allows for separation of inverters into high-voltage low-frequency and low-voltage high-frequency sections, with the low-frequency one switching at the motor's fundamental frequency.

### Conclusion

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An asymmetrical dual inverter motor drive comprising:
a first inverter, said first inverter comprised of a plurality of solid-state switching devices, wherein the first inverter is configured to invert DC power supplied by a first DC source to poly-phase AC power and supply it to the windings of a motor;
a second inverter, said second inverter comprised of a plurality of solid-state switching devices, wherein the second inverter is configured to invert DC power supplied by a second DC source to poly-phase AC power and supply it to the windings of the motor;
wherein a ratio of a voltage of the first DC source to a voltage of the second DC source is configured to be adjusted allowing output voltage levels and maximum voltage achievable at an output of each of the first inverter and the second inverter.

2. The asymmetrical dual inverter motor drive of claim 1, wherein the plurality of solid-state switching devices comprise SiC switching devices.

3. The asymmetrical dual inverter motor drive of claim 2, wherein the SIC switching devices comprise SiC MOSFETs.

4. The asymmetrical dual inverter motor drive of claim 1, wherein the plurality of solid-state switching devices comprises two solid-state switching devices per phase of the supplied poly-phase AC power.

5. The asymmetrical dual inverter motor drive of claim 1, wherein the first inverter and the second inverter further each comprise a capacitor connected in parallel with the plurality of solid-state switching devices.

6. The asymmetrical dual inverter motor drive of claim 1, further comprising a control system for firing gates of the plurality of solid-state switching devices to invert DC power supplied by the first DC source to poly-phase AC power and to invert DC power supplied by the second DC source to poly-phase AC power.

7. The asymmetrical dual inverter motor drive of claim 6, wherein the control system utilizes a model predictive control (MPC) algorithm for controlling the firing of the gates for the plurality of solid-state switching devices.

8. The asymmetrical dual inverter motor drive of claim 1, wherein the motor comprises a poly-phase open-winding permanent magnet synchronous motor (OWPMSM).

9. The asymmetrical dual inverter motor drive of claim 8, wherein the motor comprises a three-phase open-winding permanent magnet synchronous motor (OWPMSM).

10. The asymmetrical dual inverter motor drive of claim 8, wherein the motor comprises a six-phase open-winding permanent magnet synchronous motor (OWPMSM).

11. An electric aircraft comprising the asymmetrical dual inverter motor drive of claim 1.
